(19) United States
(12) Patent Application Publication
(10) Pub. No.: US 2009/0108377 A1
(43) Pub. Date: Apr. 30, 2009

(54) Method for fabricating gate dielectrics of metal-oxide-semiconductor transistors using rapid thermal processing

(76) Inventors: Zhi Chen, Lexington, KY (US); Jun Guo, Beijing (CN)

Correspondence Address: STOCKWELL & SMEDLEY, PSC, 861 CORPORATE DRIVE, SUITE 200, LEXINGTON, KY, 40503, US

(21) Appl. No.: 11/977,258

(22) Filed: Oct. 24, 2007

(51) Int. Cl. H01L 29/78; H01L 21/31

(52) U.S. Cl. 257/411; 438/762; 257/E29.255; 257/E21.24

(57) ABSTRACT

In a method for fabricating gate dielectrics of metal-oxide-semiconductor transistors, rapid thermal processing (RTP) of a gate dielectric material is performed at a temperature from 1000-1200° C. in a low-concentration oxidizing gas. The method regrows an oxide layer having a thickness of more than 0.05 nm between the gate dielectric layer and the channel region that reduces gate leakage current by 2-5 orders of magnitude and improves hot-electron reliability due to phonon-energy-coupling enhancement (PECE) effect.

### BACKGROUND OF THE INVENTION

1. Field of the Invention

Embodiments of the present invention relate generally to fabrication of metal-oxide-semiconductor (MOS) transistor devices and, more particularly, to improving the quality of gate dielectrics.

2. Description of Related Art

In modern integrated circuits (microchips), a key device, which functions as switches in logic gates, is the silicon-based metal-oxide-semiconductor field-effect transistor (MOSFET). Its size directly affects the density of components integrated into the very-large-scale integrated circuits and its performance also affects the performance of microprocessors or digital signal processors (DSP) used in personal computers and mainframe computers.

Because of increased integration, gate oxides of MOS transistors are becoming thinner and thinner and currently measure around 1-2 nm. One result is that the leakage current through the gate oxide is tending to become larger and larger which contributes to a major portion of power consumption of computer chips. One currently technique to reduce the ever-increasing gate leakage current involves using thicker high-dielectric (high-K) gate oxide materials. However, even the thickness of the high-k gate dielectrics will be scaled down, thus leading to increasing leakage current for future generations of transistors. Therefore, it is very important to find a universal principle and method, by which the leakage current of gate dielectrics can be significantly reduced.

### BRIEF SUMMARY OF THE INVENTION

Embodiments of the present invention relate to a method for fabricating gate dielectrics of metal-oxide-semiconductor transistors that performs rapid thermal processing (RTP) at a temperature from 1000-1200° C. in a low-concentration oxidizing gas. The method reduces gate leakage current by 2-5 orders of magnitude and improves hot-electron reliability due to phonon-energy-coupling enhancement (PECE) effect.

It is understood that other embodiments of the present invention will become readily apparent to those skilled in the art from the following detailed description, wherein it is shown and described only various embodiments of the invention by way of illustration. As will be realized, the invention is capable of other and different embodiments and its several details are capable of modification in various other respects, all without departing from the spirit and scope of the present invention. Accordingly, the drawings and detailed description are to be regarded as illustrative in nature and not as restrictive.

### BRIEF DESCRIPTION OF DRAWINGS

Various aspects of a semiconductor device fabrication method are illustrated by way of example, and not by way of limitation, in the accompanying drawings, wherein:

FIGS. 1-4 depict various graphs of different device characteristics resulting from embodiments of the present invention.

FIGS. 5 and 6 depict exemplary MOS transistor devices.

FIG. 7 depicts a flowchart illustrating a fabrication method in accordance with the principles of the present invention.

### DETAILED DESCRIPTION OF INVENTION

The detailed description set forth below in connection with the appended drawings is intended as a description of various embodiments of the invention and is not intended to represent the only embodiments in which the invention may be practiced. The detailed description includes specific details for the purpose of providing a thorough understanding of the invention. However, it will be apparent to those skilled in the art that the invention may be practiced without these specific details. In some instances, well known structures and components are shown in block diagram form in order to avoid obscuring the concepts of the invention.

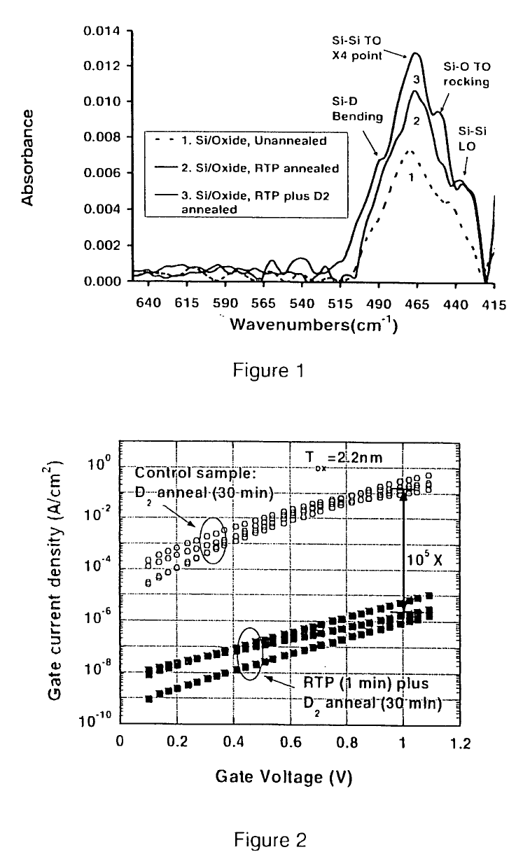

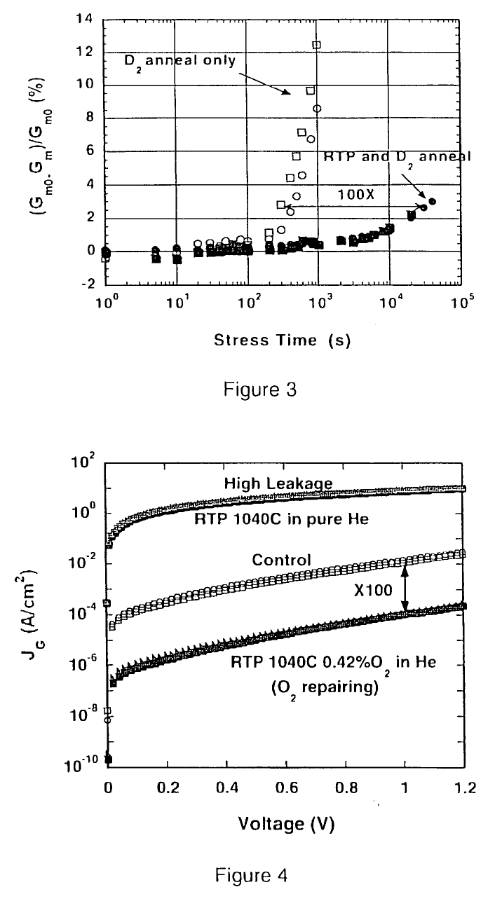

Using Fourier Transform Infrared (FTIR) spectroscopy, we discovered a new effect for the SiO₂/Si system—phonon-energy coupling enhancement (PECE), or in other words, the vibrational modes of the Si—Si, Si—O, and Si-D bonds form very strong energy coupling when a rapid thermal process (RTP) is applied to the SiO₂/Si system (See FIG. 1). The RTP process alone results in larger phonon-energy coupling among the Si—Si TO mode (468 cm⁻¹), the Si—O rocking mode (448 cm⁻¹), and the Si—Si LO mode (435 cm⁻¹) (See Curve 1 and Curve 2 in FIG. 1). It was expected that the large energy coupling may strengthen the Si—O bonds in SiO₂/Si so that the electrical performance of MOS transistors may be improved. We fabricated metal-oxide-semiconductor (MOS) capacitors and transistors to examine the impact of PECE effect on their electrical parameters. It was anticipated that when a RTP anneal is applied to silicon oxide, the leakage current will be reduced by 2-5 orders of magnitude compared to if no annealing step is performed. The leakage current of thick oxide (−10 nm) would be reduced by 2 orders of magnitude and that of thin oxide (approximately 2.2 nm) would be reduced by 5 orders of magnitude (See FIG. 2). Also, the hot-electron related lifetime of MOS transistors would be improved by 200 times over the deuterium-annealed transistors as shown in FIG. 3.

However, in fact, a RTP anneal in pure N₂ or He at a temperature of 1050° C. did not reduce leakage current but actually increased the leakage current (See FIG. 4). For example, a RTP anneal of an oxide having a thickness of approximately 2.2 nm in pure N₂ or He at a temperature >1000° C. produces destructive structures, resulting in an increase in leakage current. Therefore, there is an additional factor that causes the PECE effect, leading to the leakage current reduction. We discovered that adding a little amount of oxygen (less than approximately 5%) or moisture (less than approximately 5000 ppm), or both, to the pure N₂ or He during the RTP anneal of silicon dioxide at 1000-1200° C. with 0.1-0.2 nm oxide regrowth results in the reduction of leakage current by the 2-5 orders of magnitude illustrated in FIGS. 2 and 4. In general, oxide regrowth between about 0.06 and 0.35 nm provides the benefit of reducing leakage current. A more thorough description of these figures is provided below.

FIG. 1. illustrates the phonon-energy coupling enhancement (PECE). The following FTIR spectra of Si/SiO₂ samples (23 nm oxide) based on n⁴ wafers (n=1×10¹⁹ cm⁻³ and ρ=5×10⁻³ Ω-cm) are shown: (1) without any annealing, (2) with RTP annealing (1050° C. in nitrogen for 4 min.), and (3) with RTP (1050° C. in nitrogen for 4 min.) plus deuterium annealing (450° C. for 30 min).

FIG. 2 illustrates a reduction of gate leakage current due to the PECE effect. The graphs include the gate leakage current density of silicon dioxide (2.2 nm) on n⁴ wafers (n=1×10¹⁹ cm⁻³) with deuterium anneal only (450° C. for 30 min) and with RTP (1050° C. in nitrogen for 1.0 min.) plus deuterium anneal (450° C. for 30 min). The oxide thickness was increased by ˜0.1 nm (or 1 Å) after RTP.

FIG. 3 illustrates the improvement of Hot-electron reliability due go the PECE effect. The transconductance degradation of a MOS transistor processed in deuterium only is compared with that processed in RTP plus deuterium anneal. The MOS devices (12 μm, W=150 μm, and Tₒₓ≈20 nm) were stressed at V_{G}=5 V and V_{D}=12 V.

FIG. 4 illustrates that the RTP treatment of silicon dioxide (2.2 nm) on n-Si at 1040° C. for 60 s in pure Helium leads to higher leakage current than that of the control sample, where the oxide thickness remained 2.2 nm after RTP and, in contrast. RTP treatment at 1040° C. for 60 s in Helium carrier gas containing 0.42% O₂ (volume percentage) leads to reduced leakage current, where the oxide thickness increased by ˜0.1 nm (or 1 Å).

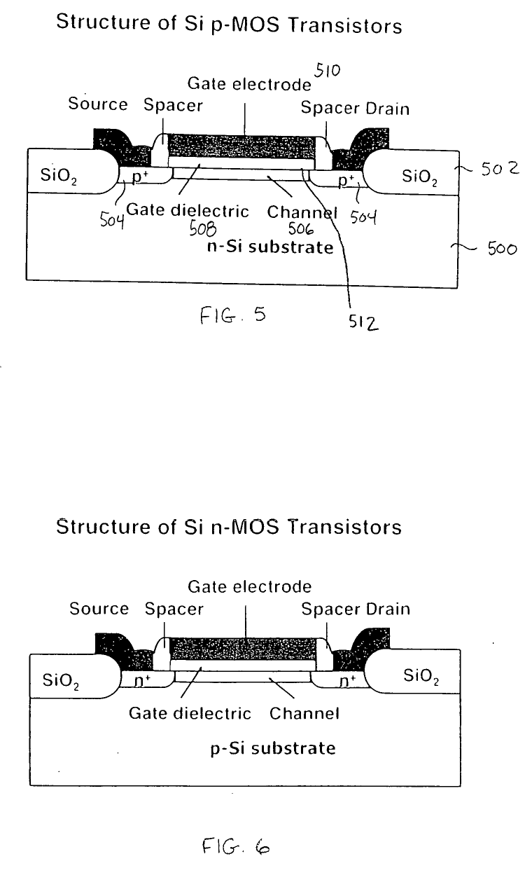

FIGS. 5 and 6 depict exemplary MOS transistors. Because FIG. 6 is conceptually the same as FIG. 5 except for the doping polarity, only FIG. 5 is discussed in detail. As shown, the p-MOS transistor of FIG. 5 includes a silicon substrate 500, isolation means 502, p+ source and drain regions 504, the channel 506, the gate dielectric 508 and the gate electrode. Such a device can be fabricated according to well know methods and steps. In addition to these well known fabrication methods, embodiments of the present invention also include modifying an RTP annealing step to repair the gate dielectric layer 508 after it is formed over the channel region 506 but before the gate electrode 510 is formed. As a result, as explained below, an oxide layer 512 is regrown on the interface between the channel region 506 and the gate dielectric layer 508 which repairs the gate dielectric layer 508 and reduces leakage current. A regrowth layer of greater than 0.05 nm and, more particularly, a regrowth layer of approximately 0.1 nm to 0.2 nm provides beneficial results without unnecessarily adding to the thickness of the gate dielectric layer 508.

We found that performing an RTP processes on a thin oxide (2.2 nm or 22 Å) at T>1000° C. in pure He (or N₂) lead to destruction of oxides which resulted in a larger leakage current yet, in general, for T<1000° C. RTP processes do not appear to damage oxides. These results suggest that a RTP at a high temperature in pure He (or N₂) induces destructive structure. This destructive Structure can be turned into a constructive structure by regrowth of ˜0.1 nm to ˜0.2 nm (−1 Å to −2 Å) oxide by introducing a little amount of oxygen (0.42% O₂ in He) during the RTP. After regrowth of ˜0.1 nm (HA) oxide, the leakage current of the oxide (˜2.3 nm or 23 Å) is reduced from about 100 A/cm² to 10⁻⁴ A/cm² (See FIG. 4). Compared to the control sample, this reduction in leakage current is equivalent to approximately a 100 times reduction of leakage current. Therefore, the leaky oxides can be repaired by introducing a little amount of oxygen during the RTP step.

Similar leakage current reduction and oxide regrowth were also observed by repairing the oxide by introducing a small amount of moisture during the RTP. One particular “small amount of moisture” that provided beneficial results included less than approximately 5000 ppm.

Although particular parameters are described herein for the rapid thermal annealing, these parameters may be modified without departing forth the scope of the present invention. For example, the temperature may be increased but applied for a longer time. Alternatively, the concentration of the oxidizing gas can be increased so that the annealing time can be reduced. The process parameters are controlled so as to result in a regrowth of a 0.06 nm to 0.35 nm ii oxide layer between the gate dielectric and the channel region. The structure of this regrowth layer provides the benefit of reducing leakage current by at least two orders of magnitude, and often more.

Embodiments of the present invention provide a process so that any gate dielectrics on silicon substrates, as long as they have Si—O bonds may exhibit reduced leakage current after they are treated by this process. At first, there is an existing dielectric in which there are Si—O bonds. They can be silicon oxides including silicon dioxide and silicon oxynitride, and high-k oxides including hafnium silicon oxide (HfSiO) and hafnium silicon oxynitride (HfSiON). All these dielectrics can be formed by various methods such as rapid thermal oxidation, plasma nitridation, sputtering, and atomic layer deposition (ALD). Thus, one of ordinary skill will recognize that a variety of different gate dielectric materials may be used without departing from the scope of the present invention. Once deposited, there are different methods for treating the gate dielectric so that the leakage current of the gate dielectric can be reduced and its reliability can be improved in accordance with the principles of the present invention. Below two specific methods are provided by way of example; however, these examples are not intended to limit the present invention to only the specific process parameters identified. One of ordinary skill will recognize that some variation of the materials and parameters may be made without departing from the scope of the present invention.

According to one particular method, during rapid thermal processing (RTP) of a gate dielectric, a little amount of oxygen is added to the RTP chamber filled with pure He or N₂, where the concentration of oxygen is less than approximately 1% (volume percentage) at one atmosphere pressure and room temperature (23° C.), i.e. O₂:He (or O₂:N₂)<1%. Then the temperature may ramp up at a moderate rate (10-25° C./s) to a high temperature between 1000° C. and 1200° C. The temperature is then held steady for 10-240 s. Finally, the samples in the RTP chamber are cooled down quickly at a rate of 30-150° C./s. These particular RTP temperatures and times result in an oxide-regrowth thickness of approximately 0.1-0.2 nm. One of ordinary skill will recognize that other process parameters resulting in a similar oxide regrowth amount may be performed as well without departing from the scope of the present invention.

In accordance with another method, during rapid thermal processing (RTP) of a gate dielectric, a little amount of moisture may be added to the RTP chamber filled with pure He or N₂, where the moisture concentration is 50-5000 ppm. This amount may, for example, be measured using a moisture analyzer. The temperature is then ramped up at a moderate rate (10-25° C./s) to a high temperature (1000° C.-1200° C.). The temperature can then be held steady for 10-240 s. Finally the samples in the RTP chamber are then cooled down quickly at a rate of 30-150° C./s. These particular RTP temperatures and times result in an oxide-re-growth thickness of approximately 0.1-0.2 ml. One of ordinary skill will recognize that other process parameters resulting in a similar oxide regrowth amount may be performed as well without departing from the scope of the present invention.

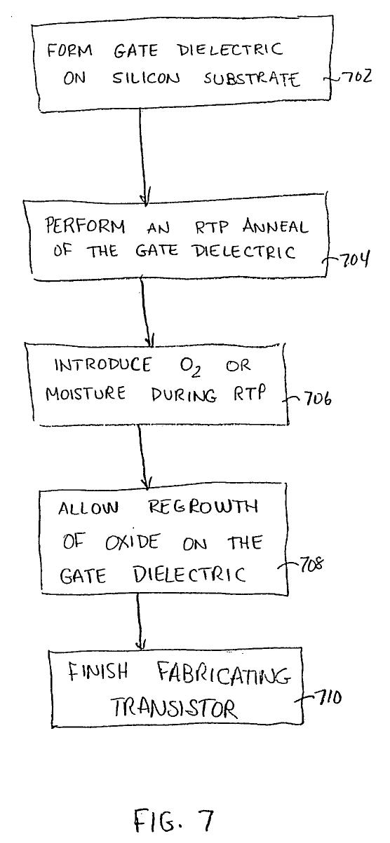

FIG. 7 depicts a flowchart outlining the steps described above relating to the RTP anneal steps of embodiments of the present invention. Using known techniques in step 702, a gate dielectric layer is formed over a channel region on a silicon substrate as part of fabricating an MOS transistor. Once formed, the gate dielectric is subject to a RTP anneal step in step 704 in an inert ambient (or, alternatively, a vacuum ambient). During this anneal step an oxidizing gas or moisture is introduced, in step 706, such that oxide regrowth occurs in step 708. In other words, the presence of oxygen or moisture during the anneal step results in oxide growing on the gate dielectric and forming a “repair” that reduces leakage current in the transistor. Thus, although shown as separate steps in the flowchart of FIG. 7, steps 704, 706, and 708 occur essentially concurrently. In step 710, the conventional fabrication steps are performed to complete the formation of the MOS transistor (as shown in FIGS. 5 and 6).

The previous description is provided to enable any person skilled in the art to practice the various embodiments described herein. Various modifications to these embodiments will be readily apparent to those skilled in the art, and the generic principles defined herein may be applied to other embodiments. For example, For example, the gate dielectric material can be one of silicon dioxide (SiO₂), chemical oxide (SiOₓ), silicon oxynitride (SION), hafnium silicon oxide (AfSiO), hafnium silicon oxynitride (HfSiON), hafnium dioxide (HfO₂), and a stack layer consisting of any two materials of the above. Also, the channel region can be made of any one of the following materials: silicon, strained silicon, silicon-germanium (SiGe), germanium (Ge), based on a substrate selected from the group of silicon, silicon-on-insulator (SOI), and silicon-on-sapphire (SOS).

As for forming the dielectric layer, the gate dielectric layer further can be formed, for example, using rapid thermal oxidation (RTO), rapid thermal nitridation (RTN), plasma nitridation, chemical solutions, atomic layer deposition (ALD), sputtering, electron-beam evaporation, physical vapor deposition (PVD), and chemical vapor deposition (CVD), and any combination among them.

Furthermore, oxygen can be introduced through various oxidizing gases such as oxygen, ozone, moisture, NO, and N₂O or any combination among them. In particular, the concentrations of oxidizing gases can be a) at room temperature (−23° C.), oxygen and ozone partial pressure is less than approximately 40 torr; b) the moisture concentration range is −48° C.-−2.4° C. dew point; and c) the NO and N₂O partial pressure is less than approximately 160 torr.

The inert ambient, for example, can be one of helium (He), nitrogen (N), argon (Ar), neon (Ne), Krypton (Kr), and Xenon (Xe) gas or any combination among them. Furthermore, the inert gas ambient may be one atmospheric pressure or less than one atmospheric pressure. The alternative vacuum ambient may be accomplished by pumping the vacuum-sealed RTP chamber below one atmosphere without supplying any inert eases.

The embodiments of the present invention contemplate a variety of gale electrode materials. For example, the electrode can be formed from any conductive material such as polycrystalline silicon (polysilicon), a metal such as aluminum (Al), titanium (Ti), tantalum (Ta), cobalt (Co), tungsten (W), and nickel (Ni)} and a metal-silicide such as TiSi, TaSi, CoSi, WSi, and NiSi, or any combination of metals and silicides, atop the gate dielectric layer.

Example Transistors that can be fabricated using the above described methods and techniques include a metal-oxide-semiconductor field-effect transistor (MOSFET); n-channel MOS transistor (NMOS), p-channel MOS transistor (PMOS), ultra-thin body silicon-on-insulator (SOI) field-effect Transistor (FET); FinFET; and multiple-gate FET.

Thus, the claims are not intended to be limited to the embodiments shown herein, but are to be accorded the full scope consistent with each claim's language, wherein reference to an element in the singular is not intended to mean “one and only one” unless specifically so stated, but rather “one or more.” All structural and functional equivalents to the elements of the various embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”.

What is claimed is:

1. A method of fabricating a gate dielectric of a semiconductor transistor, the method comprising the steps of:
fabricating the gate dielectric layer over a channel region of a substrate; and
growing an oxide layer with an thickness larger than 0.05 nm between the gate dielectric layer and the channel region by heating the gate dielectric layer to a temperature of approximately 1100° C.-1200° C. in an ambient including an oxidizing gas.

2. The method of claim 1, wherein the step of growing Occurs prior to depositing a gate electrode on the gate dielectric layer.

3. The method of claim 1, wherein heating the gale dielectric layer includes ramping up the temperature to 1000° C.-1200° C. maintaining the temperature for 0-240 s, and then cooling the gate dielectric layer down to room temperature.

4. The method of claim 1, wherein the ambient is one of either an inert gas or a vacuum ambient.

5. The method of claim 1 wherein the gate dielectric layer is comprised of a dielectric material selected from the group consisting of silicon dioxide (SiO₂), chemical oxide (SiOₓ), silicon oxynitride (SiON), silicon nitride (Si₃N₄), hafnium silicon oxide (HfSiO), hafnium silicon oxynitride (HfSiON), hafnium dioxide (HfO₂).

6. The method of claim 1, wherein the gate dielectric layer is comprised of a stack layer including any two materials selected from the group consisting of silicon dioxide (SiO₂), chemical oxide (SiOₓ), silicon oxynitride (SiON), silicon nitride (Si₃N₄), hafnium silicon oxide (HfSiO), hafnium silicon oxynitride (HfSiON), hafnium dioxide (HfO₂).

7. The method of claim 1 wherein the channel region is comprised of a material selected from the group of silicon, strained silicon, silicon-germanium (SiGe), germanium (Ge), based on a substrate selected from the group of silicon, silicon-on-insulator (SOI), silicon-on-sapphire (SOS).

8. The method of claim 1 wherein the step of fabricating the gate dielectric layer is performed using one of rapid thermal oxidation (RTO), rapid thermal nitridation (RTN), plasma nitridation, chemical solutions, atomic layer deposition (ALD), sputtering electron-beam evaporation, physical vapor deposition (PVD), chemical vapor deposition (CVD), and combinations thereof.

9. The method of claim 1 wherein heating the gate dielectric layer includes ramping up the temperature at 1-30° C./s to a final temperature, maintaining the final temperature for between 0-240 s and then cooling down at 30-150° C./s to 600° C.

10. The method of claim 9, wherein the final temperature is between approximately 1000° C. and 1200° C.

11. The method of claim 1, wherein the oxidizing gas is one selected from the group consisting of oxygen, ozone, moisture, NO, N₂O, and combinations thereof.

12. The method of claim 11, wherein at approximately 23° C. an oxygen and ozone partial pressure is less than 40 torr.

13. The method of claim 11, wherein at approximately 23° C. a moisture concentration range is −48° C.-−2.4° C. dew point.

14. The method of claim 11, wherein at approximately 23° C. a NO and N₂O partial pressure is less than 160 torr.

15. The method of claim 4 wherein the inert gas ambient is selected from the group consisting of helium (lie), nitrogen (N), argon (Ar), neon (Ne), Krypton (Kr), Xenon (Xe) gas, and combinations thereof.

16. The method of claim 4 wherein the inert Pas ambient is not greater than approximately one atmospheric pressure.

17. The method of claim 4 wherein the vacuum ambient is obtained by pumping a vacuum-sealed RTP chamber below one atmosphere without supplying any inert gases.

18. A method of treating a gate dielectric of a semiconductor transistor, the method comprising the steps of:
fabricating the gate dielectric layer over a channel region of a substrate; and
performing rapid thermal processing (RTP), in the presence of an oxidizing gas, on the gate dielectric layer before depositing a gate electrode on the gate dielectric layer; and
regrowing an oxide layer on the gate dielectric layer during rapid thermal processing, wherein the oxide layer is thicker than 0.05 nm.

19. The method of claim 18, wherein the step of performing, RTP further includes heating the gate dielectric layer to a temperature of approximately 1000° C.-1200° C. in an ambient including the oxidizing gas.

20. The method of claim 18, wherein the oxidizing gas is one selected from the group consisting of oxygen, ozone, moisture, NO, N₂O, and combinations thereof.

21. A MOS transistor comprising:
a silicon substrate having a channel region;
a gate dielectric layer formed over the channel region wherein the gate dielectric layer includes a regrown oxide layer formed during rapid thermal processing of the gate dielectric layer, wherein the regrown oxide layer is thicker than 0.05 nm; and
a gate electrode formed over the gate dielectric layer and regrown oxide layer.

22. A method of fabricating a gate dielectric of a semiconductor transistor, the method comprising the steps of:
fabricating the gate dielectric layer over a channel region of a substrate; and
deoxidizing the gate dielectric layer so that an equivalent oxide thickness of the gate dielectric is increased by more than approximately 0.05 nm by heating the gate dielectric layer to a temperature of approximately 1000° C.-1200° C. in an ambient including an oxidizing gas, wherein a concentration of the oxidizing gas is less than 100%.

23. A method of fabricating a gate dielectric of a semiconductor transistor, the method comprising the steps of:
fabricating the gate dielectric layer over a channel region of a substrate; and
growing an oxide layer having a physical thickness more than approximately 0.05 nm by heating the gate dielectric layer to a temperature of approximately 1000° C.-1200° C. in an ambient including an oxidizing gas.
